(19) United States
(12) Patent Application Publication
(10) Pub. No.: US 2013/0099288 A1
(43) Pub. Date: Apr. 25, 2013

(54) SiGe HBT and Manufacturing Method Thereof

(71) Applicant: Shanghai Hua Hong Nec Electronics Co.,Ltd., Shanghai (CN)

(72) Inventors: Fan Chen, Shanghai (CN); Xiongbin Chen, Shanghai (CN); Kai Xue, Shanghai (CN); Keran Zhou, Shanghai (CN); Jia Pan, Shanghai (CN); Hao Li, Shanghai (CN)

(73) Assignee: SHANGHAI HUA HONG NEC ELECTRONICS CO., LTD, Shanghai (CN)

(21) Appl. No.: 13/658,927

(22) Filed: Oct. 24, 2012

(30) Foreign Application Priority Data
Oct. 24, 2011 (CN) 201110326312.8

(51) Int. Cl. H01L 29/737; H01L 21/331

(52) U.S. Cl. 257/197; 438/318; 257/E29.188; 257/E21.371

(57) ABSTRACT

A silicon-germanium (SiGe) heterojunction bipolar transistor (HBT) is disclosed, in which a shallow trench is formed of a first shallow trench and a second shallow trench vertically joined together in the active region, the second shallow trench being located directly under the first shallow trench and having a width less than that of the first shallow trench; a pseudo buried layer is formed surrounding the bottom and side walls of the second shallow trench and is in contact with the collector region to serve as a connection layer of a collector; a deep hole contact is formed in the shallow trench and is in contact with the pseudo buried layer to pick up the collector. A SiGe HBT manufacturing method is also disclosed. The present invention is capable of improving the cut-off frequency of a SiGe HBT.

### CROSS-REFERENCES TO RELATED APPLICATIONS

This application claims the priority of Chinese patent application number 201110326312.8, filed on Oct. 24, 2011, the entire contents of which are incorporated herein by reference.

### TECHNICAL FIELD

The present invention relates to the fabrication of semiconductor integrated circuits, and more particularly, to a silicon-germanium (SiGe) heterojunction bipolar transistor (HBT) and a manufacturing method thereof.

### BACKGROUND

In Radio Frequency (RF) applications, higher and higher characteristic frequencies of the device are being required. Although RFCMOSs (Radio-Frequency Complementary Metal-Oxide Semiconductors) can realize higher characteristic frequencies in advanced technologies, they can hardly reach characteristic frequencies higher than 40 GHz and always lead to high costs in development of advanced technologies. For this reason, devices such as RFCMOSs made in advanced technologies are not able to completely meet the RF requirements. Although devices made by using compound semiconductors can realize extremely high characteristic frequencies, they have disadvantages of high cost of materials and small sizes. Besides, most of the compound semiconductors are toxic. Therefore, their applications are limited. In contrary, SiGe (Silicon-Germanium) HBTs (Heterojunction Bipolar Transistors) are good choices for, as well as the mainstream of, ultra-high-frequency devices for the following reasons. Firstly, they take advantage of the difference between energy bands of strained SiGe and strained Si to generate a strain effect, which can alter properties of materials, thereby improving carriers injection efficiency of emitter-region and thus increasing the current magnification of the device. Secondly, a lower base resistance and a higher characteristic frequency can be achieved through a heavily doped SiGe base region. Thirdly, the SiGe process is basically compatible with the silicon process.

In an existing SiGe HBT, a heavily-doped buried layer is formed for reducing the collector resistance and its connection is realized by performing a high-energy implantation of a high concentration of N-type ions to form a collector pick-up. The production process of the HBT includes: forming a lightly or moderately doped collector region on the buried layer by epitaxial growth; forming a base region with an in-situ P-type doped SiGe epitaxial layer and forming an emitter region with a heavily-doped N-type polysilicon. Breakdown voltage and characteristic frequency of the HBT can be adjusted by carrying out a local ion-implantation to a central area of the collector region after the emitter window is opened, and its frequency characteristic can be improved by lowering a parasitic capacitance between the collector region and the substrate through a deep trench isolation process. Though the above HBT process is relatively mature and reliable, it still has some shortcomings, mainly including: 1) a high cost is required for the epitaxial growth of the collector region; 2) in order to pick up the buried layer, a collector pick-up is formed by the high-energy implantation of a high concentration of ions, which results in a great occupied area of the device; 3) the trench isolation process is complex and high-cost; 4) a relatively great number of photoresist layers are used in the HBT process.

The applicant's co-pending U.S. patent application Ser. No. 13/198,570 discloses a modified lower-cost SiGe HBT process, in which, instead of forming the buried layer and epitaxial layer of the collector region, an N-type pseudo buried layer and a doped collector region are formed; a high dose of N-type impurities is implanted with a low energy into the bottom a shallow trench isolation region on each side of the HBT, and the buried layer is formed through the lateral diffusion of the N-type impurities; instead of forming the collector pick-up through a high-energy implantation of a high concentration of N-type ions, a deep-well contact hole is formed in the shallow trench filed oxide region by using an etching process, and a Ti/TiN transition-metal layer and tungsten are filled therein to contact with the pseudo buried layer to pick up a collector.

Nevertheless, there are also some problems in the above modified process, for example, as a shallow junction is formed according to the low-energy implantation of the N-type ions, an accordingly formed N-type pseudo buried layer is thin and thus a connection layer resistance (Rc) and a contact resistance of the collector are relatively high, which raises the difficulty to improve the cut-off frequency (Ft).

### SUMMARY OF THE INVENTION

An objective of the present invention is to provide a silicon-germanium (SiGe) heterojunction bipolar transistor (HBT) which is capable of significantly improving the cut-off frequency of a device through lowering the connection layer resistance and contact resistance of the collector and uniformizing the distribution of the contact resistance. The present invention also provides a manufacturing method of the SiGe HBT.

To achieve the above objective, the present invention provides a SiGe HBT, including: a silicon substrate; shallow trenches formed in the silicon substrate, the shallow trenches being filled with a field oxide to form shallow trench field oxide regions, each of the shallow trenches being formed of a first shallow trench and a second shallow trench vertically joined together, the second shallow trench being located directly under the first shallow trench and having a width smaller than that of the first shallow trench; an active region isolated by the shallow trench field oxide regions; a collector region, consisting of a first N-type ion-implanted region formed in the active region, a depth of the collector region being greater than that of bottoms of the shallow trench field oxide regions, the collector region having a laterally extending portion located under the shallow trench field oxide region on each side of the active region; and pseudo buried layers formed in the silicon substrate, each of the pseudo buried layers surrounding a bottom and side walls of a corresponding second shallow trench, each of the pseudo buried layers consisting of a second N-type ion-implanted region and being in contact with the collector region at the bottom and side walls of the corresponding second shallow trench for picking up a collector.

According to a preferred embodiment of the present invention, the depth of the first shallow trench is 0.2 μm to 0.3 μm; the depth of the second shallow trench is 0.05 μm to 0.3 μm; and the total depth of the shallow trench is 0.3 μm to 0.5 μm.

According to a preferred embodiment of the present invention, side walls of both the first shallow trench and the second shallow trench are tilted; the side walls of the first shallow trench have a slope of 70 degrees to 87 degrees; and the side walls of the second shallow trench have a slope of 70 degrees to 84 degrees.

According to a preferred embodiment of the present invention, the width of the first shallow trench is 0.1˜0.3 μm greater than the width of the second shallow trench.

According to a preferred embodiment of the present invention, the SiGe HBT further includes a base region consisted of a P-type SiGe epitaxial layer formed on the silicon substrate, the base region including an intrinsic base region and an extrinsic base region, the intrinsic base region being located above the active region and being in contact with the collector region, the extrinsic base region being located above the shallow trench field oxide regions, a base being picked up from the extrinsic base region.

According to a preferred embodiment of the present invention, the SiGe HBT further includes an emitter region consisted of an N-type polysilicon located on the intrinsic base region, the emitter region being in contact with the intrinsic base region, an emitter being picked up from the intrinsic base region.

To achieve the above object, the present invention also provides a method of manufacturing SiGe HBT, including:

etching a silicon substrate to form first shallow trenches;

further etching the silicon substrate to form a second shallow trench directly under each of the first shallow trenches, each second shallow trench being vertically joined together with the corresponding first shallow trench to form a shallow trench, each second shallow trench having a width smaller than that of the corresponding first shallow trench;

performing a first N-type ion implantation to the silicon substrate to form a first N-type ion-implanted region surrounding a bottom and side walls of each second shallow trench;

filling the first and the second shallow trenches with a field oxide to form shallow trench field oxide regions, an active region being isolated by the shallow trench field oxide regions;

performing a second N-type ion implantation to form a second N-type ion-implanted region in the active region;

performing an annealing process such that the second N-type ion-implanted region being diffused to form a collector region and the first N-type ion-implanted regions being diffused to form pseudo buried layers, a depth of the collector region being greater than that of bottoms of the shallow trench field oxide regions, the collector region having a laterally extending portion located under the shallow trench field oxide region on each side of the active region, each of the pseudo buried layers being in contact with the collector region at a bottom and side walls of a corresponding second shallow trench; and

picking up a collector through the pseudo buried layers.

The present invention forms a second shallow trench at the bottom of a first shallow trench and implants N-type impurity ions into the portion of the silicon substrate surrounding the bottom and side walls of the second shallow trench. By sufficiently diffusing the N-type impurities, a thicker pseudo buried layer is obtained at the bottom of the second shallow trench, so that the connection layer resistance (Rc) of the device is lowered and uniformly distributed, and therefore the cut-off frequency of the SiGe HBT is significantly improved.

### BRIEF DESCRIPTION OF THE DRAWINGS

The present invention will be described and specified below with reference to accompanying drawings and exemplary embodiments.

FIG. 1A is a schematic illustration of the structure of a SiGe HBT according to an embodiment of the present invention.

FIG. 1B is a schematic illustration of the structure of a shallow trench in the SiGe HBT of the embodiment of the present invention.

FIGS. 2A to 2D schematically illustrate structures of the SiGe HBT in steps of the manufacturing method according to an embodiment of the present invention.

### DETAILED DESCRIPTION

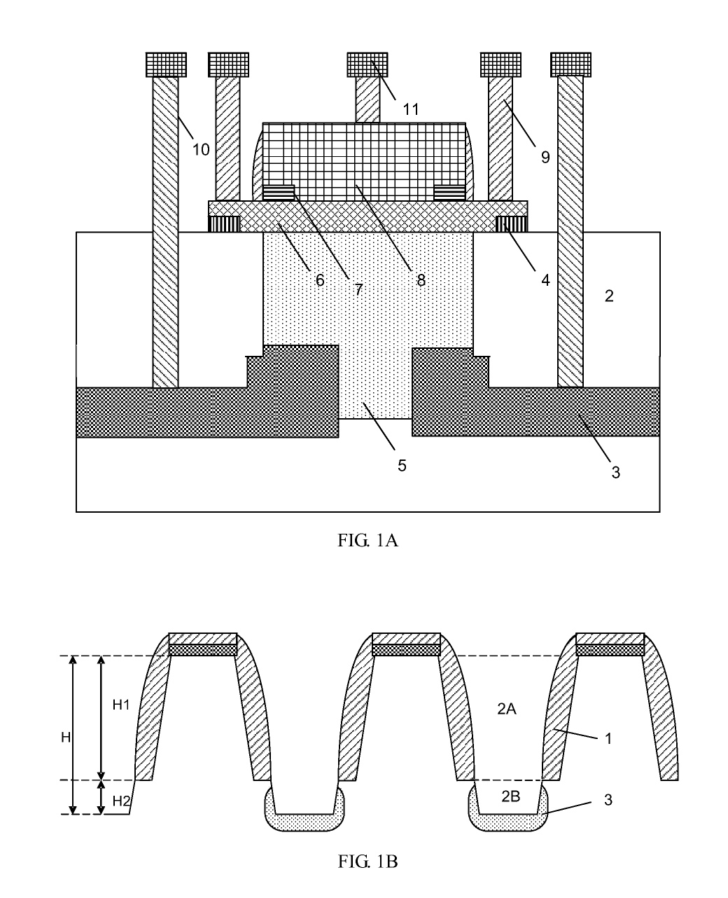

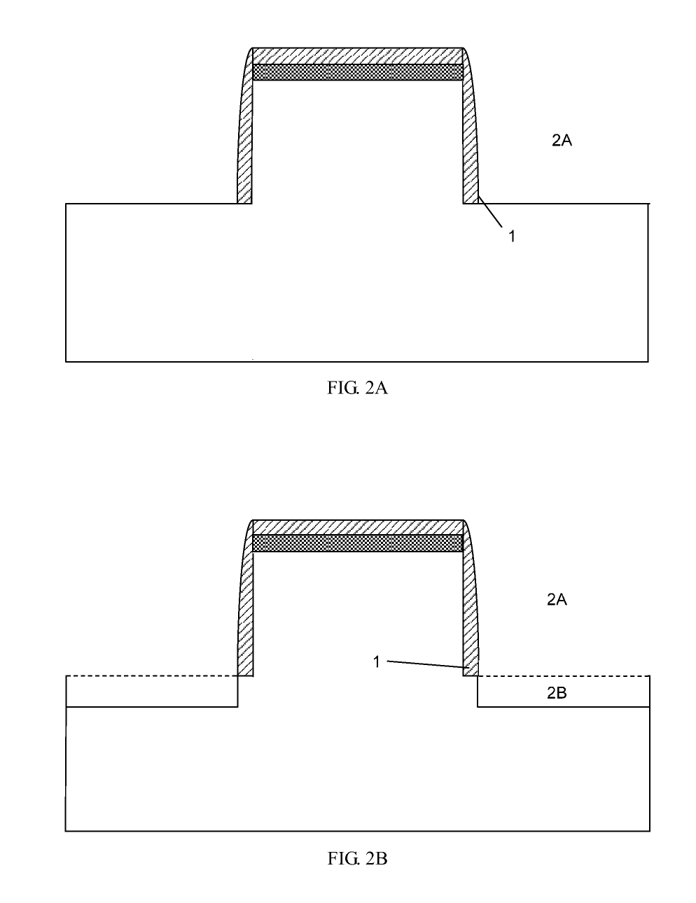

FIG. 1A schematically illustrates the structure of a silicon-germanium (SiGe) heterojunction bipolar transistor (HBT) constructed according to an embodiment of the present invention, whilst FIG. 1B schematically illustrates the structure of a shallow trench in the SiGe HBT of the embodiment of the present invention.

In this embodiment of the present invention, the SiGe HBT is formed on a silicon substrate, in which, an active region is isolated by shallow trench field oxide regions 2; a collector region 5 consists of an N-type ion implanted region formed in the active region; the bottom of the collector region 5 is deeper than the bottom of the shallow trench field oxide region 2; and the collector region 5 has a laterally extending portion located under the shallow trench field oxide region 2 on each side of the active region.

Referring to FIG. 1B, the shallow trench field oxide region 2 is formed by filling a field oxide into a shallow trench, which is composed of a first shallow trench 2A and a second shallow trench 2B. The first shallow trench 2A and the second shallow trench 2B are vertically joint together; the boundary between them is indicated by a dash line in FIG. 1B. The second shallow trench 2B is located under the first shallow trench 2A, and the width of the second shallow trench 2B is smaller than that of the first shallow trench 2A. Specifically, the difference between widths of the first shallow trench 2A and the second shallow trench 2B is approximately two times of the thickness of an inner wall spacer 1.

The depth H1 of the first shallow trench 2A is 0.2 μm to 0.3 μm, while the depth H2 of the second shallow trench 2B is 0.05 μm to 0.3 μm. And the total depth H of the shallow trench is 0.3 μm to 0.5 μm.

Side walls of both the first shallow trench 2A and the second shallow trench 2B are tilted. The side walls of the first shallow trench 2A have a slope of 70 degrees to 87 degrees, while the side walls of the second shallow trench 2B have a slope of 70 degrees to 84 degrees.

A pseudo buried layer 3 consisted of a first N-type ion-implanted region is formed in the portion of the silicon substrate surrounding the bottom and side walls of the second shallow trench 2B. The pseudo buried layer 3 serves as a connection layer of a collector. It contacts with the collector region 5 at the bottom and side walls of the second shallow trench 2B. A deep hole contact 10 is formed in the shallow trench field oxide region 2 located above the pseudo buried layer 3. The deep hole contact 10 is in contact with the pseudo buried layer 3 for picking up the collector.

The SiGe HBT further includes a base region 6 consisted of a P-type SiGe epitaxial layer 6 formed on the silicon substrate. The base region 6 includes an intrinsic base region and an extrinsic base region. The intrinsic base region is located above the active region and is in contact with the collector region 5, while the extrinsic base region is located above the shallow trench field oxide regions 3. Metal contacts 9 are formed above the extrinsic base region and are in contact with the extrinsic base region; a base is picked up from the extrinsic base region through the metal contact 9.

The SiGe HBT further includes an emitter region 8 consisted of an N-type polysilicon located on the intrinsic base region. The emitter region 8 is in contact with the intrinsic base region, and the contact area between them is defined by an emitter window which is formed of an etched dielectric layer 7. Another metal contact 9 is formed above the emitter region 8 and is in contact with the emitter region 8 to pick up an emitter. Moreover, there is a metal layer 11 used for mutual connections between these components.

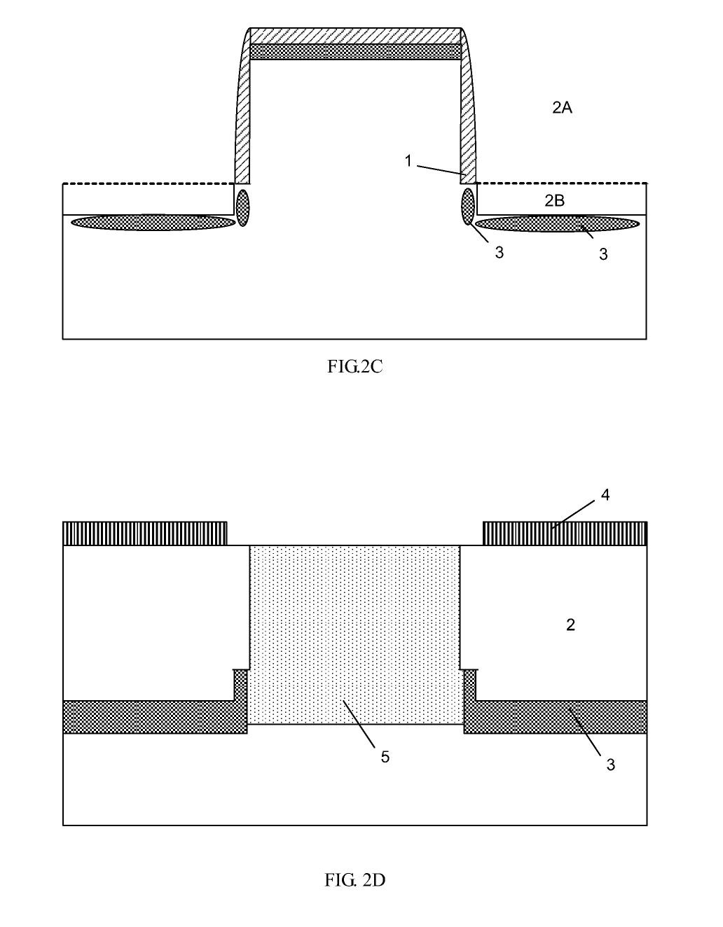

FIGS. 2A to 2D schematically illustrate structures of a SiGe HBT in steps of a manufacturing method according to an embodiment of the present invention.

The SiGe HBT manufacturing method of this embodiment of the present invention includes the following steps 1 to 9.

Step 1: as shown in FIG. 2A, a hard mask layer is formed on a substrate. The hard mask layer may consist of a first oxide film, a second oxide film and a third oxide film successively deposited on the substrate in this order, and also may consist of a first nitride film and a second nitride film successively deposited on the substrate in this order.

Next, patterns for shallow trenches and an active region are formed on the hard mask layer by using a lithography and etch process to remove a part of the hard mask layer. The remaining part of the hard mask layer covers the active region and is used to protect the active region during the subsequent etch process. Then the substrate is etched to form first shallow trenches 2A, each of which has a depth of 0.2 μm to 0.3 μm. Preferably, side walls of the first shallow trench 2A are tilted, and the slope of the side walls of the first shallow trench 2A is 70 degrees to 87 degrees. Although these side walls are marked by vertical lines in FIGS. 2A to 2D and FIG. 1A for simplicity, it should be appreciated that it does not limit the present invention in any way.

Step 2: as shown in FIG. 2A, an oxide film is deposited on the silicon substrate where the first shallow trenches 2A are formed, and an etching process is carried out to remove the part of the oxide film covering the bottoms of the first shallow trenches 2A. The remaining part of the oxide film covers the side walls of the shallow trenches 2A to form inner wall spacers 1 with a thickness of 0.05 μm to 0.15 μm.

Step 3: as shown in FIG. 2B, an etching process is applied to the whole surface of the silicon substrate by taking the hard mask layer and the inner wall spacers 1 as a mask, so as to remove a certain thickness of the unprotected part of the silicon substrate at the bottoms of the first shallow trenches 2A to form a second shallow trench 2B under each of the first shallow trenches 2A.

The depth of the second shallow trench 2B is 0.05 μm to 0.3 μm. Preferably, side walls of the second shallow trench 2B are tilted, and the slope of the side walls of the second shallow trench 2B is 70 degrees to 84 degrees. Although these side walls are marked by vertical lines in FIGS. 2B to 2D and FIG. 1A for simplicity, it should be appreciated that it does not limit the present invention in any way.

The difference between widths of the first shallow trench 2A and the second shallow trench 2B is approximately two times of the thickness of an inner wall spacer 1. The first shallow trench 2A and the second shallow trench 2B are vertically joined together and thereby constitute the above mentioned shallow trench which has a total depth of 0.3 μm to 0.5 μm.

Step 4: as shown in FIG. 2C, by taking the hard mask layer and the inner wall spacers 1 as a mask, a first N-type ion implantation is performed to form a first N-type ion implanted region 3 in the portion of the silicon substrate surrounding the bottom and side walls of the second shallow trench 2B. The first N-type ion implantation is performed with an implantation dose of 1e14 cm⁻² to 1e16 cm⁻² and an implantation energy of 2 KeV to 20 KeV. After that, the first N-type ion implanted regions 3 are treated by a rapid thermal annealing process for 5 seconds to 30 seconds at a temperature of 980 degrees centigrade to 1050 degrees centigrade.

Step 5: the hard mask layer covering the active region is removed by using a wet strip process.

Step 6: as shown in FIG. 2D, the inner wall spacers 1 are removed and a field oxide is filled into the shallow trenches to form shallow trench field oxide regions 2; a base-region oxide layer 4 is deposited onto the surface of the silicon substrate and is etched to expose the active region of the SiGe HBT; phosphorus ions are implanted into the active region, and an annealing process is performed. After the annealing process, the phosphorus ions implanted into the active region are diffused to form a collector region 5, and the N-type impurities in the first N-type ion implanted regions 3 are also diffused to form pseudo buried layers 3. The pseudo buried layers 3 serve as a connection layer of a collector and are in contact with the collector region 5 at the bottom and side walls of the corresponding second shallow trench 2B.

Step 7: as shown in FIG. 1A, a base region 6 is formed by growing a P-type SiGe epitaxial layer 6 on the silicon substrate. The base region 6 includes an intrinsic base region and an extrinsic base region. The intrinsic base region is located above the active region and in contact with the collector region, while the extrinsic base region is located above the shallow trench field oxide regions 2; a base is picked up from the extrinsic base region.

Step 8: as shown in FIG. 1A, a dielectric layer 7 is deposited and etched to form an emitter window which defines a contact area between an emitter 8 described below and the intrinsic base region.

After that, an N-type polysilicon is deposited and etched to form the emitter 8 which is located above the intrinsic base region and is in contact with the intrinsic base region.

Step 9: as shown in FIG. 1A, a deep hole contact 10 is formed in each of the shallow trench field oxide region 2 located above the pseudo buried layer 3; the deep hole contact 10 is in contact with the pseudo buried layer 3 and a collector is picked up through the deep hole contact 10; a metal contact 9 is formed on each side of the extrinsic base region and is in contact with the extrinsic base region to pick up a base; another metal contact 9 is formed above the emitter region 8 and is in contact with the emitter region 8 to pick up an emitter; and at last, a metal layer 11 is formed for mutual connections between these components.

The above specific embodiments are provided for the object of describing the invention solely and are not intended to limit the scope of the invention in any way. Those skilled in the art can make various variations and modifications without departing from the spirit or scope of the invention. Thus, it is intended that the present invention cover these modifications and variations.

What is claimed is:

1. A silicon-germanium (SiGe) heterojunction bipolar transistor (HBT), comprising:
a silicon substrate;
shallow trenches formed in the silicon substrate, the shallow trenches being filled with a field oxide to form shallow trench field oxide regions, each of the shallow trenches being formed of a first shallow trench and a second shallow trench vertically joined together, the second shallow trench being located directly under the first shallow trench and having a width smaller than that of the first shallow trench;
an active region isolated by the shallow trench field oxide regions;
a collector region, consisting of a first N-type ion-implanted region formed in the active region, a depth of the collector region being greater than that of bottoms of the shallow trench field oxide regions, the collector region having a laterally extending portion located under the shallow trench field oxide region on each side of the active region; and
pseudo buried layers formed in the silicon substrate, each of the pseudo buried layers surrounding a bottom and side walls of a corresponding second shallow trench, each of the pseudo buried layers consisting of a second N-type ion-implanted region and being in contact with the collector region at the bottom and side walls of the corresponding second shallow trench for picking up a collector.

2. The SiGe HBT according to claim 1, wherein a depth of the first shallow trench is 0.2 μm to 0.3 μm; a depth of the second shallow trench is 0.05 μm to 0.3 μm; and a total depth of the shallow trench is 0.3 μm to 0.5 μm.

3. The SiGe HBT according to claim 1, wherein side walls of both the first shallow trench and the second shallow trench are tilted; the side walls of the first shallow trench have a slope of 70 degrees to 87 degrees; and the side walls of the second shallow trench have a slope of 70 degrees to 84 degrees.

4. The SiGe HBT according to claim 1, wherein a width of the first shallow trench is 0.1˜0.3 μm greater than that of the second shallow trench.

5. The SiGe HBT according to claim 1 further comprising a base region consisted of a P-type SiGe epitaxial layer formed on the silicon substrate, the base region including an intrinsic base region and an extrinsic base region, the intrinsic base region being located above the active region and being in contact with the collector region, the extrinsic base region being located above the shallow trench field oxide regions, a base being picked up from the extrinsic base region.

6. The SiGe HBT according to claim 5 further comprising an emitter region consisted of an N-type polysilicon located on the intrinsic base region, the emitter region being in contact with the intrinsic base region, an emitter being picked up from the intrinsic base region.

7. A method of manufacturing silicon-germanium (SiGe) heterojunction bipolar transistor (HBT), comprising:
etching a silicon substrate to form first shallow trenches;
further etching the silicon substrate to form a second shallow trench directly under each of the first shallow trenches, each second shallow trench being vertically joined together with the corresponding first shallow trench to form a shallow trench, each second shallow trench having a width smaller than that of the corresponding first shallow trench;
performing a first N-type ion implantation to the silicon substrate to form a first N-type ion-implanted region surrounding a bottom and side walls of each second shallow trench;
filling the first and the second shallow trenches with a field oxide to form shallow trench field oxide regions, an active region being isolated by the shallow trench field oxide regions;
performing a second N-type ion implantation to form a second N-type ion-implanted region in the active region;
performing an annealing process such that the second N-type ion-implanted region being diffused to form a collector region and the first N-type ion-implanted regions being diffused to form pseudo buried layers, a depth of the collector region being greater than that of bottoms of the shallow trench field oxide regions, the collector region having a laterally extending portion located under the shallow trench field oxide region on each side of the active region, each of the pseudo buried layers being in contact with the collector region at a bottom and side walls of a corresponding second shallow trench; and
picking up a collector through the pseudo buried layers.

8. The method according to claim 7 further comprising forming a base region by growing a P-type SiGe epitaxial layer on the silicon substrate after the annealing process, the base region including an intrinsic base region and an extrinsic base region, the intrinsic base region being located above the active region and being in contact with the collector region, the extrinsic base region being located above the shallow trench field oxide regions, a base being picked up from the extrinsic base region.

9. The method according to claim 8 further comprising forming an emitter region by growing an N-type polysilicon on the intrinsic base region after forming the base region, the emitter region being in contact with the intrinsic base region, an emitter being picked up from the intrinsic base region.

10. The method according to claim 7, wherein the collector is picked up through a deep hole contact formed in the shallow trench field oxide region located above the pseudo buried layer.

11. The method according to claim 7, wherein a depth of the first shallow trench is 0.2 μm to 0.3 μm; a depth of the second shallow trench is 0.05 μm to 0.3 μm; and a total depth of the shallow trench is 0.3 μm to 0.5 μm.

12. The method according to claim 7, wherein side walls of both the first shallow trench and the second shallow trench are tilted; the side walls of the first shallow trench have a slope of 70 degrees to 87 degrees; and the side walls of the second shallow trench have a slope of 70 degrees to 84 degrees.

13. The method according to claim 7, wherein a width of the first shallow trench is 0.1˜0.3 μm greater than that of the second shallow trench.
